(19) United States
(12) Patent Application Publication
(10) Pub. No.: US 2001/0031546 A1
(43) Pub. Date: Oct. 18, 2001

(54) Method of manufacturing a semiconductor device

(75) Inventors: Margriet Lisette Diekema, Nijmegen (NL); Antonius Maria Petrus Johannes Hendriks, Nijmegen (NL)

Correspondence Address: Michael E. Marion, Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/829,795

(22) Filed: Apr. 10, 2001

(30) Foreign Application Priority Data
Apr. 12, 2000 (EP) 00201318.3

(51) Int. Cl. H01L 21/3205; H01L 21/4763

(52) U.S. Cl. 438/592; 438/683

(57) ABSTRACT

In a method of manufacturing a semiconductor device, a p+region is formed in a silicon body, which p+region is provided with a low ohmic phase of titanium silicide by means of silicidation of the silicon body. In order to promote the formation of the low ohmic phase of titanium silicide, the p+region is formed by implanting B ions and BF₂ ions into the silicon body in a ratio between 1:4 and 4:1.

The present invention relates to the field of integrated circuit devices and more in particular to silicidation of shallow implanted junctions of p-type semiconductor technologies, e.g. p-doped Metal Oxide Semiconductor (pMOS) technologies, using boron ions to form the junctions.

For instance in high performance complementary Metal Oxide Semiconductor (CMOS) technologies, minimum dimensions for both MOSFETs (Metal Oxide Semiconductor Field Effect Transistors) are required to obtain a high speed. Proper well engineering and drain engineering are needed to avoid short channel effects within small MOSFETs, and especially within small pMOSFETs.

Most approaches to the problem of reducing short channel effects and punch-through in a pMOSFET are based on the formation of extremely shallow junctions, which are highly doped drains, HDD regions. The present invention relates to the silicidation, especially the salicidation (self-aligned silicidation), and preferably titanium salicidation of these shallow junctions.

Conventional techniques for the formation of shallow junctions generally make use of implantation of either positive B ions or positive BF₂ ions. Both ions, however, have their specific problems. B ions penetrate deeply and give rise to more lateral diffusion after annealing, causing short channel effects. BF₂ ions may be used for shallow junctions and have a good transistor performance, but a negative effect on the silicidation step due to the presence of fluorine ions in and on the surface.

Furthermore, a number of techniques make use of both BF₂ and B ion doping in one manufacturing process.

For instance, in WO-A-99/35680 it is described that boron penetration can be suppressed in the manufacture of CMOS by using low energy B (¹¹B⁺, acceleration voltage lower than 7,000 volts) ions rather than BF₂ implantation for P+poly gate and S/D doping. The reduction in boron penetration observed with B is large when compared to that of BF₂, which is attributed to the absence of fluorine, which—when present—enhances boron diffusion through SiO₂. In addition, it was found that although boron penetration through the gate oxide is suppressed, the diffusivity of B in silicon is substantially higher as compared with BF₂. This latter effect leads to a lateral spread of the P+implant into a BF₂ drain extension during rapid thermal annealing (RTA). In order to reduce this diffusivity effect, or in case this step lead to problems associated with nMOS transistor considerations and in particular to diode leakage, it is proposed to reduce the S/D RTA temperature by coimplantation of a B/BF₂ junction with a small fraction of BF₂.

U.S. Pat. No. 5,225,357 describes a method of manufacturing a PMOS integrated circuit comprising: providing a pattern of silicon gate electrodes over a gate dielectric on a silicon substrate, followed by the formation of a heavily doped drain by implanting BF₂⁺ions and implanting ¹¹B⁺ions—preferably in this order—while using said pattern as a mask, and subsequently annealing at a temperature above 850° C. The construction thus obtained is completed by depositing an insulating layer of silicon oxide or borophosphosilicate glass (BPSG) and depositing metal layers above and on the sides of contact openings as provided. This method is said to result in a lower contact resistance to the P⁺regions and lower sheet resistance for higher speed CMOS integrated circuits.

These prior art documents do not relate to methods wherein titanium silicide is formed on the P⁺areas formed.

Furthermore, it has been described in Japanese patent application 63-146183 (NEC Corp.) that deviation of P⁺/N diffusion layer characteristics and deterioration of P⁺/N junction breakdown voltage can be eliminated by forming a high melting point metal silicide film on a semiconductor substrate where a P⁺/N diffusion layer is formed. More in detail, adjacent to a gate polysilicon layer a P⁻ diffusion layer is formed by impregnating a Si substrate with B ions followed by a heat treatment. Then, an oxide film is formed over the surface, followed by etching back, giving a side wall oxide layer to the gate polysilicon electrode. Subsequently, a part of the P⁻ diffusion layer is impregnated with BF₂, followed by a heat treatment giving a P⁺diffusion layer. After formation of a titanium film over the entire surface, annealing is performed followed by etching, forming a titanium silicide film on the gate electrode and the P⁺diffusion layer. Finally, a silicon oxide film is accumulated and aluminum electrodes are formed.

As said hereinabove, it is an object of the present invention to scale down integrated circuits wherein short channel effects are reduced by the formation of extremely shallow junctions. The invention particularly aims at providing proper silicidation and especially salicidation of the shallow junctions. It has been found that the incomplete transformation of titanium silicide from the stable high ohmic C49 phase to the low ohmic C54 phase constitutes a problem to BF₂ implanted, highly doped drains (p+Source/Drain (S/D)). This leads to higher sheet resistances. Problems and effects associated with the use of BF₂ implantation on titanium silicide formation have been described in e.g. Choi et al. J. Appl. Phys. 72 (1992), 297-299 and in Georgiou et al. J. Electrochem. Soc. 139 (1992), 3644-3648. Said documents mainly focus on diode leakage and the physical characterization of the silicide layer formed.

Implantation of B instead of BF₂ was found to improve the silicidation transformation of silicide on the p+S/D regions (p+active regions) and p+polysilicon gates to the C54 phase. However, the implantation of B ions for S/D implantation gives rise to more short channel effects, such as in particular transistor leakage and punch-through, and increases the occurrence of boron penetration.

It is an object of the present invention to provide devices containing shallow junctions, which devices have a very good transistor performance, while the junctions can be silicided without problems. In other words, the present invention aims to provide devices which combine the positive effects of B implantation and BF₂ implantation, yet do not have the adverse effects of implanted B and BF₂ ions.

In accordance with the present invention, it has now been found that if both B and BF₂ are used for p+S/D in a certain ratio, the titanium silicide phase transformation of C49 to C54 on p+active and p+poly silicide becomes essentially complete. The C54 phase has a low resistance as compared to the C49 phase, which means that the circuit speed in the device can be improved by converting the C49 phase to the C54 phase. Especially in small structures, it was difficult, if possible at all, using prior art techniques, to effect a phase transition to the C54 phase.

Hence, the present invention relates to a method of manufacturing a semiconductor device, wherein a p+region is formed in a silicon body, which p+region is provided with a low ohmic phase of titanium silicide by means of silicidation of the silicon body, characterized in that the p+region is formed by implanting B ions and BF₂ ions into the silicon body in a ratio between 1:4 and 4:1, preferably between 1:3 and 3:1. More preferably the ratio of B to BF₂ is about 1:1. The most optimum ratio of B to BF₂ depends on device and circuit behaviour and be easily determined by a person of ordinary skill in the art can on the basis of the information in the present specification. Furthermore, the mixture of B and BF₂ should be dosed in dependece upon the technology required. For a 0.35 micron CMOS technology, a 1:1 mixture with a total dose of 2-5 10¹⁵ cm⁻² is suitable.

In a preferred embodiment of the method of the invention the BF₂ ions are implanted first and subsequently the B ions are implanted. This embodiment profits from the known pre-amorphisation effect on the silicide during BF₂ implantation.

As the stopping power for BF₂ ions is higher than that for B ions, B ions are implanted at energies which are generally in the range from 2-10 eV, preferably not higher than 8 and most preferably not higher than 7 eV. BF₂ ions can be implanted at energies of 10-50 eV.

The implantation of B and BF₂ ions has the advantage that it is less susceptible to variations in energylevel. Especially for B ions this advantage is critical, since a small variation in the energy has a pronounced effect on the penetration of B ions, also in lateral directions. Because of this advantage, the process of the invention is more suitable for standard implantation tools.

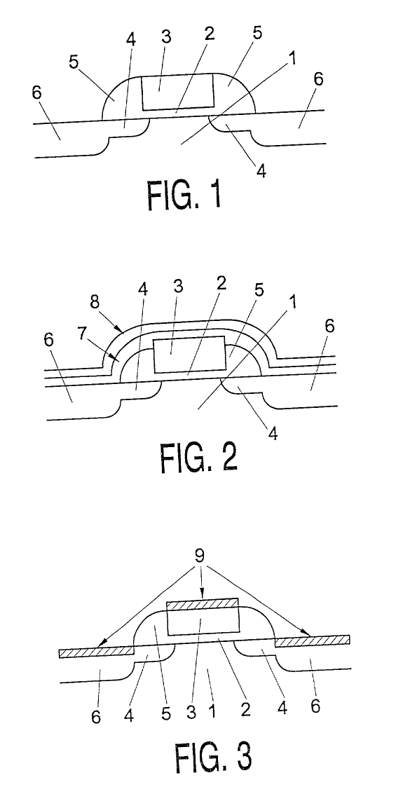

The invention will be elaborated in more detail, while referring to FIGS. 1 to 3, which are not intended to limit the scope of the invention. FIGS. 1 to 3 give an overview of a salicidation process that can be used in the method of the present invention.

In FIG. 1, a typical pMOSFET is shown, comprising a silicon substrate provided with an N-well region 1 and a field oxide region (not shown). On the silicon substrate a gate oxide layer 2 and a polysilicon gate electrode 3 are formed. Subsequently, impurity ions are implanted in the silicon substrate to form lightly doped drain (LDD) regions 4. Side wall spacers 5 are formed on the sides of the gate electrode 3. Shallow Highly Doped Drains 6 are implanted with As for the nMOSFET and B in combination with BF₂ for the pMOSFET in accordance with the present invention, followed by a thermal treatment to form a source/drain region. Subsequently, this device is silicidized using conventional techniques, resulting in a device as depicted in FIG. 3. As shown in FIG. 2, a titanium layer 7 is deposited, e.g. a layer with a thickness of about 20-50 nm, and subsequently a surface TiN layer 8 is deposited in a thickness of e.g. about 10-30 nm, followed by a rapid thermal annealing step (RTA) under a nitrogen atmosphere. In this RTA, titanium and silicon react to form a titanium silicide film 9 of the stable C49 phase. Unreacted titanium and the surface film of titanium nitride are selectively removed, e.g. while using a mixture of sulfuric acid and aqueous hydrogen peroxide (FIG. 3). This process results in titanium-silicidized S/D regions and poly-Si gates.

The structure of FIG. 3 is subsequently subjected to a second temperature step, comprising heating to a temperature above 800° C., and preferably between 820 and 950° C., in order to form the low ohmic C54 silicide phase in accordance with the present invention. More in particular, it is noted that in accordance with the present invention it turned out that the influence of the p+S/D implantation on the transformation and especially on the completeness of the transformation of C49 to C54 titanium silicide is large. In prior art methods, the transformation was either not complete or was associated with a reduced transistor behaviour. Using the method in accordance with the present invention the transistor performance is essentially maintained.

Without being bound by any theory, it is assumed that if only BF₂ ions are used, the surface of the implanted region becomes passivated by fluorine atoms. When a smaller amount of BF₂ ions are used, the performance of the device decreases, because the saturation current and the circuit speed decrease. The B ions are needed to compensate for the lack of BF₂ ions.

The total amount of positive ions implanted in the S/D is generally lower than 5·10¹⁵ cm⁻², and suitably in the range from 1-4.5·10¹⁵ cm⁻².

In preferred embodiments, the combined implantation of positive B ions and positive BF₂ ions can be combined with other methods that may improve the C49 to C54 phase transformation. One of these other methods consists of increasing the layer thickness of the Ti layer 7 in FIG. 2, e.g. from 25 nm to 40 or even 50 nm. Another such method is used to increase the temperature of the first RTA step in the silicidation. Further, it is possible to introduce a second rapid temperature annealing step, while the selective etch step after the Ti/TiN deposition as illustrated in FIG. 2 should be as short as possible. Alternatively the TiN layer can be reduced in thickness, or can even be absent, leading to devices having a lower resistance.

Dependent on the technology used, the person skilled in the art is capable of finding suitable process conditions enabling a compromise to be made between salicidation, leakage paths between p+poly and p+active, and cracking of the silicide.

1. A method of manufacturing a semiconductor device, wherein a p+region is formed in a silicon body, which p+region is provided with a low ohmic phase of titanium silicide by means of silicidation of the silicon body, characterized in that the p+region is formed by implanting B ions and BF₂ ions into the silicon body in a ratio of B to BF₂ between 1:4 and 4:1.

2. A method as claimed in claim 1, characterized in that the ratio of B to BF₂ is about 1:1.

3. A method as claimed in claim 1 or 2, characterized in that first BF₂ ions are implanted and subsequently B ions.

4. A method as claimed in any one of the preceding claims, characterized in that the total amount of positive B and BF₂ ions implanted is smaller than 5·10¹⁵ cm⁻², and preferably is in the range from 1.0·10¹⁵ to 4.5·10¹⁵ cm⁻².
